(19) United States
(12) Patent Application Publication
(10) Pub. No.: US 2007/0224350 A1
(43) Pub. Date: Sep. 27, 2007

(54) Edge coating in continuous deposition line

(75) Inventor: Mikael Schuisky, Sandviken (SE)

Correspondence Address: DRINKER BIDDLE & REATH (DC), 1500 K STREET, N.W., SUITE 1100, WASHINGTON, DC, 20005-1209, US

(73) Assignee: SANDVIK INTELLECTUAL PROPERTY AB

(21) Appl. No.: 11/384,259

(22) Filed: Mar. 21, 2006

(51) Int. Cl. B05D 5/00; C23C 16/00; B05D 3/00; B44C 1/22; C23F 1/00

(52) U.S. Cl. 427/251; 427/284; 427/294; 427/295; 216/37; 156/345.31; 118/718; 118/719

(57) ABSTRACT

A continuous roll-to-roll deposition coating apparatus and a method to continuous coat an edge of a strip substrate are disclosed. The continuous roll-to-roll deposition coating apparatus has one or more deposition zones and one or more targets arranged in a position and orientation relative to an edge region of the strip substrate to obtain the desired coating. Position and orientation can include relative angles, displacement distance and translation position of the targets relative to the edge region. A method to continuously coat an edge region of a strip substrate in a continuous roll-to-roll deposition coating apparatus is also disclosed.

### FIELD OF THE INVENTION

The present disclosure relates to a continuous deposition coating apparatus and methods to continuously deposit coatings on edges of substrates, such as, for example, metal strip substrates. More specifically, the present disclosure relates to a coated steel strip material with a hard, dense and/or low friction coating. It also relates to a method of manufacturing such a coated steel strip in a continuous roll-to-roll process which results in a very good adhesion of a hard, dense and/or low friction coating on a metal strip substrate. The coated steel strips, which have a good adhesion of the coating, are suitable for use in, for example, coater and doctor blades, shaving equipment, medical instruments, utility and industrial knives as well as saw applications or other applications using a metal strip substrate with a coated edge.

### BACKGROUND

In the discussion that follows, reference is made to certain structures and/or methods. However, the following references should not be construed as an admission that these structures and/or methods constitute prior art. Applicant expressly reserves the right to demonstrate that such structures and/or methods do not qualify as prior art.

Coated steel products can be used in various applications. One example is in the manufacture of knives, such as utility knives, e.g., slicers, carving knives, bread knives, butcher's knives, mixer blades, hunting and fishing knives, pocket knives, and industrial knives for cutting synthetic fiber, paper, plastic film, fabrics and carpets. Furthermore, these products can be used in saw applications and as medical instruments and surgical knives. Another example is in shaving applications, such as razor blades and cutters. A further example includes doctor and coater blades, such as those used in the manufacturing of paper and in the printing industry to scrape paper and printing ink, respectively, from a surface. In connection to this, problems often arise with wear on the surface and on the coater or doctor blade. Coater and doctor blades are normally manufactured from hardened steel strips. One common way of reducing the wear problem is to apply an abrasion resistant coating to the steel blade after it has been manufactured to its final geometry in the form of a coater or doctor blade. In connection to this, usually a nickel layer must be applied to act as a bond-coat between the substrate and the abrasion resistant coating. Just to name a few examples.

These are all applications where a hard and dense wear coating may be suitable, or even needed. Wear can, for example, result in the coating being torn off or cracking. These are also applications which need to have hard and sharp edges and cutting surfaces. Furthermore, many of the applications listed above are used in corrosive environments and therefore benefit from a corrosion resistant surface.

Thus, it is known that abrasion resistant coatings can be used, but there are difficulties to find a cost-efficient and environmentally friendly method that can meet the required quality. The cost for a coater or doctor blade with an applied abrasion resistant coating is at present very high. Moreover, the cost for a quality problem occurring during usage in a printing industry or in a paper mill is high. Also, frequent blade changes increase costs.

The good adhesion of a coating on an edge is needed for the functional quality of the finished product. A poor adhesion, or a porous or coarse coating, would cause problems during usage of the coated object, for example, an industrial knife or saw, e.g., that the coating starts to flake off, that grains or small pieces are torn off, or that fissure problems occur. All in all, this is not acceptable from a quality and cost perspective.

There are several common methods of making a coating and also several different types of coatings that are being used. As examples can be mentioned:

Ceramic coatings, often consisting of Al₂O₃ with possible additions of TiO₂ and/or ZrO₂. This type of coating is normally applied by using a thermal spray method. An example of a thermal spray method is described in, e.g., U.S. Pat. No. 6,431,066, in which a ceramic coating is applied along one edge of a doctor blade. Another example of a thermal spray method is described in EP-B-758 026, in which a wear resistant coating is applied along one edge using several coating steps in a rather complicated continuous process including thermal spray.

Conventional thermal spray methods have generally some major drawbacks. For example, the formed coating is rough which means that polishing or other further processing must usually be done to the surface after the coating. Also, a thermal spray coating usually includes a high degree of porosity, implying that a thin dense coating normally can not be achieved. Furthermore, the thickness of thermal sprayed coatings is normally rather high. During usage, a thick and coarse coating has an increased risk of fissure formation or that grains tear off from the surface. In many cases expensive nickel or nickel alloys must also be used as a bond-coat in order to improve the adhesion of the ceramic coating.

Conventional metallic coatings, often consisting of pure nickel or chromium, or in the form of a compound such as nickel-phosphorus, are normally applied by using a plating method, and especially electrolytic plating. Electrolytic plating methods have some drawbacks, one major drawback being the difficulty to obtain an even thickness and also that the adhesion of the coating can be poor. Also, plating processes are not environmentally friendly; on the contrary, these processes often include environmental problems.

Combinations of coatings, such as a nickel coating comprising abrasion resistant particles, e.g., SiC, are described in WO 02/46526, in which different layers are applied in a continuous process for electrolytic nickel coatings in several steps and by adding abrasive particles to at least one of these steps. This method also has some drawbacks, in principle the same drawbacks as for electrolytic plating as described above, but also that nickel is used to a large extent as a bond-coat, meaning that the coating is very expensive.

### SUMMARY

A hard and abrasion resistant coated metal strip with improved adhesion between a dense coating and the substrate is disclosed. For cost reasons, a continuous roll-to-roll coating process is preferred; said line can coat one or more strip edges in the same roll-to-roll coating process. Further, for quality reasons, a dense coating with very good adhesion to the substrate is of advantage. From a cost perspective, it is also a further advantage if there is such a good adhesion of the abrasion resistant coating that there is optionally no need of any separate bond-coat.

An exemplary embodiment of a continuous roll-to-roll deposition coating apparatus comprises a vacuum process chamber including an etching zone upstream of a deposition zone, at least one ion assisted etcher in the etching zone, and at least one deposition apparatus in the deposition zone, wherein the at least one deposition apparatus includes at least one target, wherein the strip substrate, in traveling through the vacuum process chamber, projects a first edge region toward the at least one ion assisted etcher in the etching zone and projects the first edge region toward the target of the at least one deposition apparatus in the deposition zone, wherein the first edge region of the strip substrate includes at least a first angled surface tapered from a first proximal position toward a first distal position, the first proximal position closer to a center region of the strip substrate than the first distal position, the first angled surface having a first surface normal, and wherein the target of the at least one deposition apparatus includes a target surface having a target normal and is angled with respect to the first angled surface so that the target normal intersects the first surface normal at an angle α, where α is greater than or equal to 90 degrees.

An exemplary embodiment of a method to continuous coat an edge of a strip substrate, comprises supplying at least one strip substrate to a vacuum process chamber, the strip substrate including a body, a first main side opposing a second main side and a first lateral side opposing a second lateral side, the first and second lateral sides more narrow that the first and second main sides, moving the at least one strip substrate through the vacuum process chamber, the vacuum process chamber including at least one ion assisted etcher in an etching zone and at least one deposition apparatus in a deposition zone, the etching zone upstream of the deposition zone, cleaning a first edge region of the at least one strip substrate in the etching zone, the first edge region including at least a first angled surface tapered from a first proximal position toward a first distal position, the first proximal position closer to a center region of the strip substrate than the first distal position, the first angled surface having a first surface normal, depositing a coating on the first angled surface of the first edge region in the deposition zone, and collecting the coated strip substrate, wherein the at least one deposition apparatus includes at least one target, wherein the at least one strip substrate, in traveling through the vacuum process chamber, projects the first edge region toward the at least one ion assisted etcher in the etching zone and projects the first edge region toward the at least one target of the at least one deposition apparatus in the deposition zone, and wherein the target of the at least one deposition apparatus includes a target surface having a target normal and is angled with respect to the first angled surface so that the target normal intersects the first surface normal at an angle α, where α is greater than or equal to 90 degrees.

Another exemplary continuous roll-to-roll deposition coating apparatus, comprising a vacuum process chamber including an etching zone upstream of a deposition zone, at least one ion assisted etcher in the etching zone, and at least one deposition apparatus in the deposition zone, wherein the at least one deposition apparatus includes at least one target. The strip substrate, in traveling through the vacuum process chamber, projects a first edge region toward the at least one ion assisted etcher in the etching zone and projects the first edge region toward the target of the at least one deposition apparatus in the deposition zone. The first edge region of the strip substrate is squared off and has a first proximal position and a first distal position, the first proximal position closer to a center region of the strip substrate than the first distal position, the first edge region having a first surface normal. The target of the at least one deposition apparatus includes a target surface having a target normal and is angled with respect to the first edge region so that the target normal intersects the first surface normal at an angle α, where α is greater than or equal to 90 degrees.

### BRIEF DESCRIPTION OF THE DRAWINGS

The following detailed description of preferred embodiments can be read in connection with the accompanying drawings in which like numerals designate like elements and in which:

FIG. 1 shows schematically a production line for the manufacturing of a coated metal strip according to one disclosed embodiment.

FIG. 2 shows schematically the production line for the manufacturing of a coated metal strip as seen along line A-A of FIG. 1.

FIG. 3 shows various example edge geometries and various example coatings on edge geometries.

FIG. 4 shows a schematic cross-section of an optional arrangement for the plurality of strip substrates.

FIGS. 5a and 5b show another exemplary relationship between the projection distance d of a strip substrate, the separation distance in the y-axis direction between sequential strip substrates y and the angle from the vertical, γ and γ′, of each of the targets.

### DETAILED DESCRIPTION

A dense and abrasion resistant coating with good adhesion properties and a continuous deposition coating apparatus are disclosed. The coating on a final product, such as a strip substrate in the form of a hardenable strip steel, is a suitable coating for the use in applications using a metal strip substrate with a coated edge, for example, in shaving equipment, medical instruments, utility and industrial knives, saw applications, doctor and coater blade applications, or creping blades for use in creping of paper in the manufacturing of paper. A suitable coating for use in the above mentioned applications has a dense layer of an abrasion resistant coating with good adhesion, which is hard but also tough enough to withstand the work-load and pressure during usage, with reduced or no tendency to brittleness or tearing off. Low friction coatings can also be used, alone or in combination with other properties of the coatings.

Description of the Coating Materials and Arrangement:

Abrasion resistance can be achieved by depositing, for example, a coating with at least one layer of dense transition metal nitride or mixtures of these nitrides, such as TiN, ZrN, TiAlN, ZrAlN, VN, TiVN, VAlN, CrN, Cr₂N, CrAlN, MoNx, WNx, preferably a layer of a TiN or CrN-based material. Depending on the requirements, an optimum of required hardness, toughness and/or corrosion resistance can be achieved by using mixed nitrides in the coating. This can be achieved by selectively choosing the alloy composition of the target material for deposition, e.g., for deposition by arc-evaporation or sputter deposition. Multilayer coatings may also be used in order to enable a combination of nitrides so as to optimize hardness and toughness by having up to 20 sublayers in the multilayer coating with different nitrides in the sublayers, with optional carbide additions in the sublayers or separate carbide-based sublayers.

Abrasion resistance can also be achieved by depositing, for example, a coating with at least one layer of dense metal carbide material in the form of TiC, ZrC, VCx, CrCx, MoCx, WC, or mixtures of these carbides, preferably layer of a TiC, WC or a CrCx-based material. Depending on the requirements, an optimum of required hardness and toughness and corrosion resistance can be achieved by using mixed carbides in the coating. This can be achieved by choosing the alloy composition of the target material for deposition, e.g., for deposition by arc-evaporation or sputter deposition. Multilayer coatings may also be used in order to enable a combination of carbides so as to optimize hardness and toughness by having up to 20 sublayers in the multilayer coating with different carbides in the sublayers, with optional nitride additions in the sublayers or separate nitride-based sublayers.

Carbonitrides, such as Ti(C,N), can also be used in the coatings or in the sublayers, either alone or in mixtures.

Abrasion resistance or low friction can be achieved by depositing, for example, a coating with at least one layer of dense diamond like carbon layer (DLC). Said DLC layer can be mixed with minor amounts of transition metals such as Ti, Ta, W and/or Cr. Depending on the requirements, an optimum of required hardness and toughness and corrosion resistance and friction can be achieved by using effective amounts of transition metal addition, up to about 20%, alternatively up >0 to about 10%. This can be achieved by choosing the alloy composition of the target material for deposition, e.g., for deposition by arc-evaporation or sputter deposition. Multilayer coatings may also be used in order to enable a combination of DLCs so as to optimize hardness and toughness by having up to 20 sublayers in the multilayer coating with different nitrides in the sublayers, with optional carbide additions in the sublayers or separate carbide-based sublayers.

As an alternative to the above-described abrasion resistant layer consisting of essentially nitrides, other coatings such as metallic coatings can be used in the disclosed embodiments. Metallic coatings, such as essentially pure Ti, Zr, V, Nb, Ta, Cr, W, Fe, Mo, Ni, and Fe or alloys of these materials, such as TiAl, NiAl and FeCrAlY, may be used if a simple and cheap coating is to be preferred in order to reduce cost as much as possible. Thin layers of pure metallic coatings such as described here, e.g., the metallic coatings, can also be used as a bond coat layer between the strip steel edge and a second coating, where the second coating can have a composition including a transition metal nitride or carbide or metal containing diamond like carbon (Me-DLC, where Me is a transition metal such as Ti, Ta, Cr and W) or a diamond like carbon (DLC) layer.

As an alternative to abrasion resistance and/or low friction DLC coatings, materials containing MAX phases can be deposited. A MAX phase material is a ternary compound with the following formula Mₙ₊₁A_{z}Xₙ. M is at least one transition metal selected from the group of Ti, Sc, V, Cr, Zr, Nb, Ta; A is at least one element selected from the group consisting of Si, Al, Ge and/or Sn; and X is at least one of the non-metals C and/or N. The ranges of the different components of the single phase material is determined by n and z, wherein n is within the range of 0.8-3.2 and z is within the range of 0.8-1.2. Consequently, examples of compositions within the MAX phase material group are Ti₃SiC₂, Ti₂AlC, Ti₂AlN and Ti₂SnC. In addition to pure MAX phase coatings, composite coatings including MAX phases may also be deposited.

There is no need of any separate bond-coat, but metallic coating elements such as nickel or titanium may still optionally be used in one of the layers if it is desired from a technical perspective, e.g., to enhance toughness. In regards to nickel, since nickel is expensive, it is usually used in very thin layers only, suitably between 0 to 2 μm, preferably between 0 to 1 μm and most preferably between 0 to 0.5 μm. However, any possible nickel layer, if used, would not be the layer adjacent to the strip substrate.

The methods disclosed and described herein are suitable for thin coatings of hard and dense abrasion resistant coatings in thicknesses on each side of an edge region of a strip substrate up to 25 μm in total, normally up to 20 μm in total, preferably up to 15 μm in total. A maximum 12 μm or preferably maximum 10 μm in total is preferable from a cost perspective. If thicker coatings are to be coated, an optimum in cost versus properties may be achieved by using multi-layers with up to 10 layers, and where each layer is between 0.1 to 15 μm thick, suitably between 0.1 to 10 μm, or more suitably 0.1 to 7 μm, preferably 0.1 to 5 μm and even more preferably 0.1 to 3 μm. Other suitable coating thicknesses include ≦10 μm, ≦5 μm, and ≦1 μm.

The coating should be sufficiently wear-resistant in order to withstand the wear and shear exerted by the treated material, on the other hand it should not be too thick, due to economical reasons and fragility/brittleness. For example, for coater blade and doctor blade applications, the ratio between the thickness of the coating and the substrate material can be between 0.1% to 12%, normally 0.1 to 10% and usually 0.1 to 7.5% but most preferably between 0.1 to 5%.

Description of the Substrate Material to be Coated:

The material to be coated should have a good basic mechanical strength, suitable for the intended application. In one example, the strip substrate is a hardenable steel in a hardened and tempered condition, or alternatively a precipitation hardenable steel, such as the alloy disclosed in WO 93/07303, which in the end condition can achieve a tensile strength level above 1200 MPa, or preferably more than 1300 MPa, or at the best above 1400 MPa, or even 1500 MPa.

If the final coated product is intended for use in a corrosive environment, then the steel alloy of the strip substrate should also have a sufficient addition of chromium to enable a good basic corrosion resistance. For example, the Cr content can be above 10% by weight, or at least 11%, or preferably a minimum of 12%.

The coating method may be applied on any kind of substrate made of said type of steel alloy and in the form of a strip that has good hot workability and also can be cold-rolled to thin dimensions. The alloy also typically can be capable of readily being manufactured to the desired final product, such as a coater or doctor blade applications, shaving equipment like razor blades and/or cutters, medical instruments, utility and industrial knives, various saws and other strip product applications, in a manufacturing process including steps such as forming, grinding, shaving, cutting, polishing, stamping, or the like. The thickness of the strip substrate is usually between 0.015 mm to 5.0 mm and suitably between 0.03 mm to 3 mm. Preferably, it is between 0.03 to 2 mm, and even more preferably between 0.03 to 1.5 mm. The normal thickness for coater blades range from 0.3 up to 1.0 mm, while for doctor blades it ranges from 0.1 up to 0.4 mm and for razor blades the normal thickness range of the strip material is 0.076 up to 0.1 mm. The width of the strip substrate material and the shape of the edge to be coated depends on intended use of the final product. Further, the width can optionally be selected to be a width suitable for further manufacturing to the final width of the coated product. Appropriate example widths are 1 to 500 mm, suitably 1 to 250 mm, or preferably 1 to 100 mm, depending on the final product. The length of the strip substrate material is suitably between 10 and 20,000 m, preferably between 100 and 20,000 m. The strip substrate material is generally in a coil for handling both before and after applying the coating. Naturally, the dimensions of the strip substrate are adapted to the intended use of the final product and other minimum and maximum thicknesses can be suitably employed.

Description of the Coating Method and Apparatus:

A variety of physical or chemical vapor deposition methods for the application of the coating media/material and the coating process may be used as long as they provide a continuous uniform and adherent coating. As exemplary of deposition methods, can be considered chemical vapor deposition (CVD), metal organic chemical vapor deposition (MOCVD), physical vapor deposition (PVD) such as sputtering and evaporation by resistive heating, by electron beam, by induction, by arc resistance or by laser deposition methods. Arc-evaporation or sputtering, particularly magnetron sputtering, are two example methods preferred for the deposition.

Although the deposition apparatus is referred to and disclosed herein at some points by reference to the arc-evaporation and sputter deposition methods, the disclosure, principles and methods can apply analogously to the other types of deposition methods and techniques. Thus, it will be understood by one of ordinary skill in the art that while discussing deposition apparatus generally or arc-evaporation and sputtering specifically, other deposition methods are within the disclosure of the application.

The coating method is integrated in a roll-to-roll strip production line and the coating is deposited by a selected deposition apparatus, for example, by means of arc-evaporation or sputtering, in a roll-to-roll continuous deposition coating apparatus. If multi-layers are needed, the formation of multi-layers can be achieved by integrating several arc-evaporation or sputtering targets in-line in the deposition chamber(s). Furthermore, coatings on the edge portion of the strip substrate can be controlled by orienting the targets at suitable angles to the surface on which the coatings are to be deposited.

The deposition of metallic coatings is made from metallic targets under reduced atmosphere at a maximum pressure of 1×10⁻² mbar with no addition of any reactive gas to promote essentially pure metal films. The deposition of metal carbides and/or nitrides, such as TiN, TiC, CrN, CrCx, VN, TiAlN and CrAlN, is made from metallic targets with the addition of reactive gases. Metal carbides and metal carbonitrides such as TiC and Ti(C,N) can also be deposited from composite targets containing both a transition metal and carbon. The conditions during the coating can be adjusted with regard to the partial pressure of a reactive gas so as to enable the formation of the intended compound. In the case of nitrogen, a reactive gas such as N₂, NH₃ or N₂H₄, but preferably N₂, may be used. In the case of carbon, any carbon containing gas may be used as reactive gas, for an example CH₄, C₂H₂ or C₂H₄. The deposition of metal oxides is performed under reduced pressure with an addition of an oxygen source as reactive gas in the chamber.

To enable-good adhesion, different types of cleaning steps are used. First, the surface of the substrate material is cleaned to remove oil residues, which otherwise may negatively affect the efficiency of the coating process and the adhesion and quality of the coating. Moreover, the very thin native oxide layer that normally is present on a steel surface is removed. This can preferably be done by including a pre-treatment of the surface before the deposition of the coating. In the roll-to-roll production line, the first production step is a cleaning step, for example, preferably an ion assisted etching of the metallic strip substrate surface to achieve good adhesion of the first coating.

The coating is performed at a rate of minimum 0.1 meters per minute, preferably min 0.5 m/min, most preferably min 1 m/min. The rate of movement of the strip substrate can be dependent on the number of targets and the deposition rate of the deposition technique, with more targets increasing the deposition rate and, therefore, allowing an increased rate of movement of the strip substrate to be used.

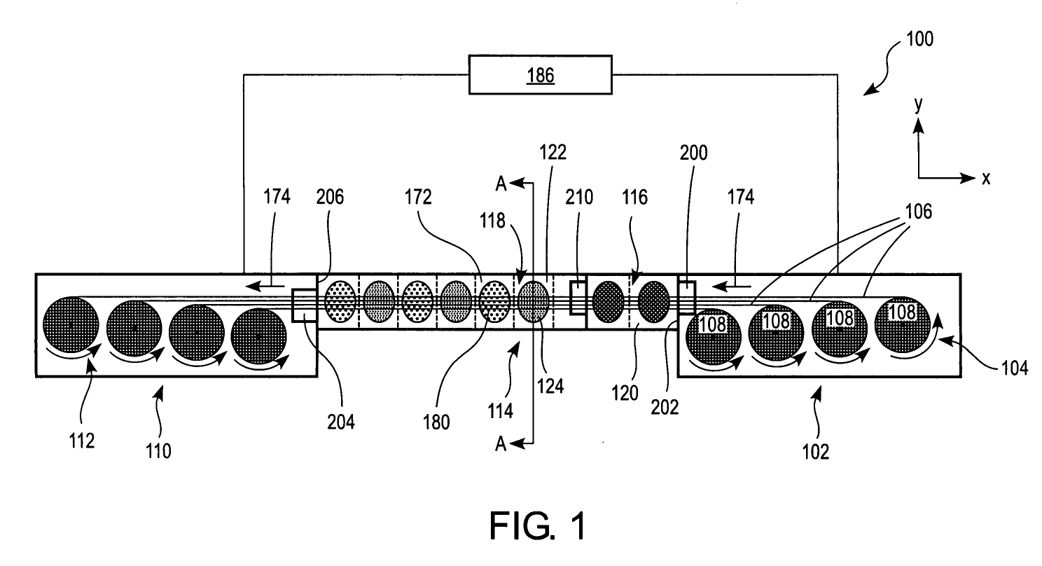

FIG. 1 shows schematically an example of a production line for the manufacturing of a coated metal strip according to a first disclosed embodiment. In FIG. 1, the production line for the manufacturing of a coated metal strip is illustrated as continuous roll-to-roll deposition coating apparatus 100. The continuous roll-to-roll deposition coating apparatus 100 comprises a supply chamber 102 including an uncoiler 104 for each of a plurality of strip substrates 106, each arranged in a coil 108, and a collection chamber 110 including a recoiler 112 for each of the plurality of strip substrates 106. A vacuum process chamber 114 is positioned between the supply chamber 102 and the collection chamber 110. The vacuum process chamber 114 includes an etching zone 116 upstream of a deposition zone 118. At least one ion assisted etcher 120 is positioned in the etching zone 116 and at least one deposition apparatus 122, which includes at least one target 124, is positioned in the deposition zone 118.

In the illustrated continuous roll-to-roll deposition coating apparatus 100, four separate strip substrates are shown. However, it is to be understood that the continuous roll-to-roll deposition coating apparatus 100 can have any number of strip substrates. For example, from 1 to 10 or even more strip substrates can be used. In another example, the continuous roll-to-roll deposition coating apparatus 100 could have up to 100 of strip substrates in the line when forming strip substrates for razor blade applications, but may only have four strip substrates in the line if designed for forming strip substrates for coater and or doctor blade applications. Generally, the more strips you include the more productive the line becomes but it also becomes much more complex.

The components of the ion assisted etcher 120, including inert gas plasma generating equipment to produce a plasma to impact the strip substrate, are operatively arranged within the vacuum process chamber 114 to remove the thin oxide layer on the strip substrate material prior to deposition of the coating.

The components of the arc-evaporator 122, including arc generating equipment for producing an arc and evaporation target, or sputterer 122, including a sputter source and sputtering target, are operatively arranged within the vacuum process chamber 114 to deposit a coating on the strip substrate 106 as it passes through the vacuum process chamber 114.

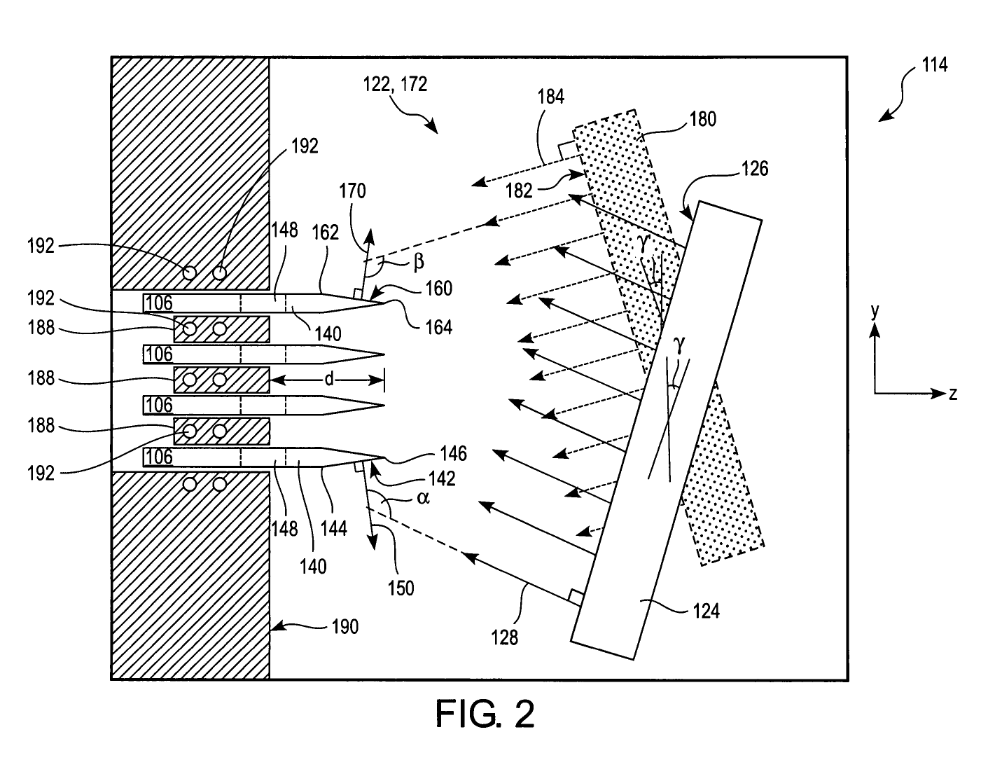

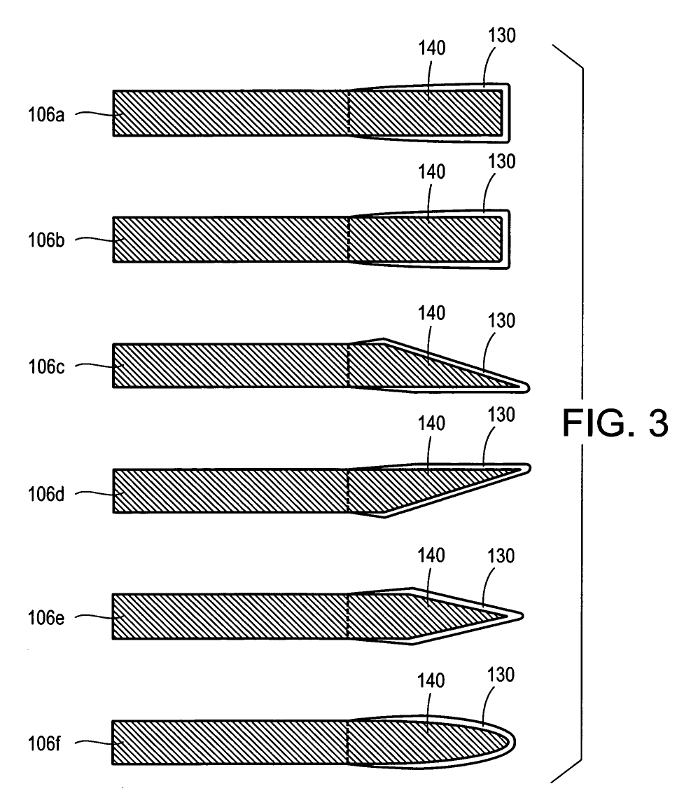

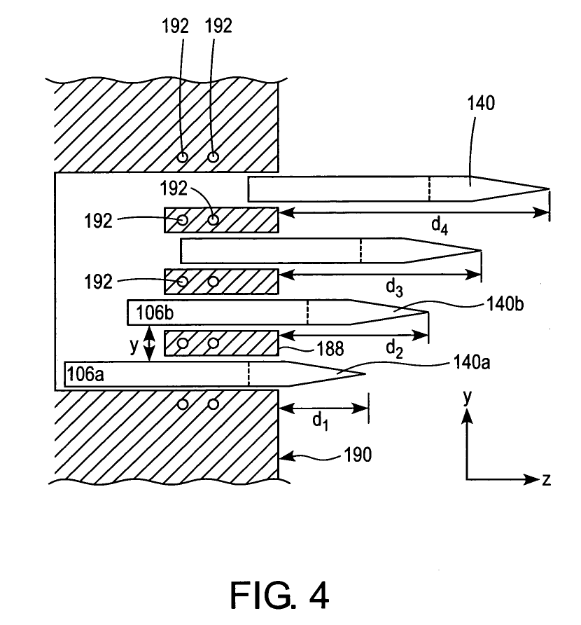

Lateral sides of the strip substrate can be coated. For example and as shown in FIG. 1, the strip substrate 106 from each of the plurality of coils, in traveling from the supply chamber 102 through the vacuum process chamber 114 to the collection chamber 110, projects a first edge region (an example of which is shown at 140 in FIGS. 2 and 3 and at 140′, 140″, 140′″ and 140″ in FIG. 4) toward the at least one ion assisted etcher 120 in the etching zone 116 and projects the first edge region toward the target 124 of the at least one arc-evaporator or sputterer 122 in the deposition zone 118.

In exemplary embodiments and as shown in FIG. 2, the first edge region 140 of the strip substrate 106 includes at least a first angled surface 142 tapered from a first proximal position 144 toward a first distal position 146. The first proximal position 144 is depicted as closer to a center region 148 of the strip substrate 106 than the first distal position 146. However, the location of the first proximal position on the strip substrate is not limited and may, in optional embodiments, be at an opposite end of the strip substrate from the first edge region such that the taper of the angled surface extends across a full dimension of the strip substrate.

In some embodiments, the first distal position 146 of the first angled surface 142 is coextensive with an edge of the strip substrate 106, e.g., one of the lateral sides of the strip substrate 106. The first angled surface 142 has a first surface normal 150. In FIG. 1, the strip substrate 106 is viewed from the lateral side and the first edge region 140, including the first angled surface 142, is in a direction into the view, projecting toward the targets 124.

FIG. 3 shows various example edge geometries and various example coatings on the example edge geometries. In FIG. 3, variations of the strip substrate 106 are shown with a coating 130. As seen in FIG. 3, a strip substrate 106a can, at the first edge region 140, be squared off and have a coating 130 that encapsulates the first edge region. Also shown in FIG. 3 are strip substrates 106b-106e having various geometries for the first edge region 140, including squared off (106a), squared off with rounded or chamfered corners (106b), tapered on one side (106c and 106d), tapered on both sides (106e), and rounded (106e). The tapered portions can terminate in an angle or can be rounded or chamfered. In each case, the coating 130 conforms or substantially conforms to the shape of the underlying first edge region 140. At the limit of the deposition, the coating 130 can optionally feather into the surface of the underlying strip substrate 106.

The surfaces of the first edge region 140 of the strip substrate 106 have specific spatial relationships with the targets 124. These relationships allow, for example, multiple strip substrates arranged vertically spaced (e.g. arranged spaced in the y-axis direction) to each be cleaned by the ion assisted etcher 120 and to each have a coating deposited by the deposition apparatus 122 as the strip substrates pass through the zones of vacuum process chamber 114. The multiple strip substrates can also optionally be horizontally displaced (e.g., arranged staggered a distance dₙ in the z-axis direction as shown in FIG. 4) to allow each to be cleaned by the ion assisted etcher 120 and to each have a coating deposited by the deposition apparatus 122 as the strip substrates pass through the zones of the vacuum process chamber 114.

In one embodiment, the target 124 of the deposition apparatus 122 is angled from the vertical a desired angle, represented by y in FIG. 2. In embodiments with multiple targets 124, such as for depositing coatings of more than one material and/or for depositing coatings on more than one side of the first edge region of the strip substrate, successive targets or groups of targets can be used.

Each target 124 can be positioned for a desired coating effect. For example, successive targets or groups of targets can be angled at different angles from the vertical a desired angle, represented by γ and γ′ in FIG. 2. In general, each target is mounted on a target holder (not shown), which may be individualized to each target, or may collectively hold more than one target. The target holder is pivotable about a pivot point and/or movable in multiple directions and/or movable in combinations resulting in skew manipulation and has at least one-degree of freedom, preferably at least two-degrees of freedom or three-degrees of freedom. A target holder can be manually manipulated during set-up of the continuous roll-to-roll deposition coating apparatus 100 or can be remotely controlled through a controller interface to allow in-situ changes in the position of the target holder. Such a remote control can, for example, be through manipulating piezoelectrics, pneumatics, or other electronic or mechanical devices to change the position and orientation of the target holder relative to a calibrated position or orientation.

One of the degrees of freedom can be pivoting about an axis located in the x-direction so that a surface of the target is angled with respect to the surface of the strip substrate to be coated. This type of movement is shown in FIG. 2 where angles γ and γ′ of the targets 124 can be any desired angle. In some embodiments, the angles γ and γ′ are selected to maximize the deposition of coatings on the first edge regions 140 of the strip substrates 106. In some embodiments, the angles γ and γ′ are selected to minimize shadowing of first edge regions by other adjacent or near first edge regions during the deposition of coatings or to obtain a desired shadowing effect. In some embodiments, the above considerations are both considered and a balanced approach is used. γ and γ′ can be the same angle, complimentary angles, mirror images across a horizontal reference plane, or can be different, as needed to obtain the desired coating effect.

For example, the target of the at least one arc-deposition apparatus 122 includes a target surface 126 having a target normal 128. The target surface 126 is angled with respect to the first angled surface 142 of the first edge region 140 so that the target normal 128 intersects the first surface normal 150 at an angle α. In one example, the angle α is greater than or equal to 90 degrees. In another example, the angle α is from 90 to 135 degrees.

Similar angular relationships for more than one target can be developed and implemented in the continuous roll-to-roll deposition coating apparatus 100 and can apply to both targets of deposition apparatus in the deposition zone 118 as well as to targets for ion assisted etchers in the etching zone 116.

Another of the degrees of freedom can be displacement in the z-direction (as shown in the axes of FIG. 2) whereby the targets 124, 180 are positioned at a distance from the first edge region 140. A change in the distance between the targets 124, 180 and the first edge region 140 can influence the rate of deposition and the quality of the coating. A further degree of freedom is translation in the y-direction (as shown in the axes of FIG. 2) whereby the targets 124, 180 are positioned at a different height with respect to the first edge region 140. A translation of the targets 124, 180 relative to the first edge region 140 can influence the rate of deposition and the quality of the coating.

The degrees of freedom of the target can accommodate coating multiple surfaces of one or more strip substrates by the maneuvering of the targets through the degrees of freedom. In one example, the target holder is mounted on a backside, e.g., the side opposite the surface 126, 182 of impingement, and the target holder includes rails, racks and/or gears to provide the necessary degrees of freedom.

For example, in some embodiments the first edge region 140 of the strip substrate 106 has more than one surface to be coated and/or more than one surface that is angled. For example, an edge of the strip substrate, a first and/or second main side of the strip substrate, whether angled or not, and/or a combination of these surfaces can have a coating deposited thereon in the deposition zone.

For example, the first edge region 140 of the strip substrate 106 can include a second angled surface 160 on an opposite main side of the strip substrate 106 from the first angled surface 142. The second angled surface 160 is tapered from a second proximal position 162 toward a second distal position 164. The second proximal position 162 is closer to the center region 148 of the strip substrate 106 than the second distal position 164. In some embodiments, the second distal position 164 of the second angled surface 160 is coextensive with an edge of the strip substrate 106, e.g., one of the lateral sides of the strip substrate 106. In some embodiments, the first distal position 146 of the first angled surface 142 and the second distal position 164 of the second angled surface 160 are coterminous and form a knife-edge. The second angled surface 164 has a second surface normal 170. In FIG. 2, the strip substrate 106 is viewed from one of the lateral sides and the first edge region 140, including the second angled surface 160, is in a direction into the view, projecting toward the evaporation targets 124.

The continuous roll-to-roll deposition coating apparatus can have multiple deposition apparatus in the vacuum process zone, e.g., arc-evaporators or sputterers. For example, an embodiment of a continuous roll-to-roll deposition coating apparatus can comprise a second (or more) deposition apparatus in the deposition zone (as, for example, shown schematically in FIG. 1 (six targets) and FIG. 2 (two targets)). In these examples, a second (or subsequent) deposition apparatus 172 is downstream, in a process flow direction, e.g. in direction 174 in FIG. 1, from the at least one deposition apparatus 122. As with the at least one deposition apparatus 122, the second (or subsequent) deposition apparatus 172 includes a target 180. The second target 180 of the second deposition apparatus 172 includes a target surface 182 having a target normal 184 and is angled with respect to the second angled surface 160 so that the target normal 184 intersects the second surface normal 170 at an angle β. In one example, the angle β is greater than or equal to 90 degrees. In another example, the angle β is from 90 to 135 degrees. In still other examples, α can equal β or a can be different from β.

Subsequent deposition apparatus can be included in the continuous roll-to roll deposition coating apparatus 100 and also each can include a target. In FIG. 1, for example, six deposition apparatus are shown, each with a separate target 124, and the targets 124 are shown alternating with different angles γ and γ′ (like-angled targets are represented by like shading in FIG. 1) and, by extension, different angles α and β. However, different angles for each target can be employed as desired to achieve different coating effects and it is not required that the targets be like-angled. Further, the target source of the first deposition apparatus can be the same material or a different material than the target source of the second deposition apparatus and/or the target source of any subsequent deposition apparatus.

FIG. 1 illustrates an optional controller 186 operatively connected to the uncoiler 104 for each of the plurality of strip substrate 106 arranged in a coil 108 and the recoiler 112 for each of the plurality of strip substrates 106. The controller 186 controls the speed of supply and collection of the strip substrate 106 through the vacuum process chamber 114 to attain a desired tension of the strip substrate 106 in the deposition zone 118.

As mentioned herein, multiple strip substrates can be arranged vertically spaced (e.g. arranged spaced in the y-axis direction), optionally be horizontally displaced (e.g., arranged staggered in the z-axis direction) and further optionally a combination of the two. For example and as shown in FIG. 2, the plurality of strip substrates 106 can be spaced apart vertically (e.g. arranged spaced in the y-axis direction) with an optional spacer 188 between successive strip substrates 106. In another example and as shown in FIG. 2, the projecting first edge region 140 of each of the plurality of strip substrates 106 project the same distance d from an interior surface 190 of the vacuum process chamber 114.

In some examples, the first distal position 146 and/or the second distal position 164 of each of the plurality of strip substrates 106 are staggered. As way of example, the first distal position of a lowermost strip substrate can be at a first distance and the first distal position of an uppermost strip substrate can be at a second distance, the second distance greater than the first distance. As way of another example, the first distal position 146 of each of the plurality of strip substrates 106 between the lowermost strip substrate and the uppermost strip substrate is at a graduated distance between the first distance and the second distance.

FIG. 4 shows an optional combination horizontally displaced (e.g., displaced along the z-axis) and vertically displaced (e.g., displaced along the y-axis) arrangement. As an example, the vertical displacement dₙ, n=1, 2, 3, . . . , and the horizontal displacement y can be such that one of the strip substrates 106′ does not block deposition of material on a first edge region 140″ of a next strip substrate 106″ during the deposition process, e.g., does not shadow the next strip substrate. Vertical and horizontal displacement of subsequent strip substrates can analogously have distances to minimize or prevent shadowing during the deposition process.

In FIG. 4, the projecting first edge region 140′, 140″, 140′″, 140″″ of each of the plurality of strip substrates 106′, 106″, 106′″, 106″″ project a different distance dₙ, n=1, 2, 3, . . . , from an interior surface 190 of the vacuum process chamber 114, e.g., are horizontally displaced (e.g., arranged staggered in the z-axis direction). The spacer 188 and other portions of the deposition zone, such as the wall of the interior surface 190, can be cooled by, for example, fluid or gas flow through cooling channels 192.

It is to be appreciated that the apparatus in the etching zone, e.g., the ion assisted etcher, has a target that can also optionally be angled, displaced or translated in one or more degrees of freedom similar to the angling, displacement and translation of the one or more targets of the deposition apparatus.

The continuous roll-to-roll deposition coating apparatus 100 can optionally be under atmospheric controls, e.g., vacuum or specified atmosphere, or optionally portions of the continuous roll-to-roll deposition coating apparatus 100 can be under such atmospheric controls. For example, the vacuum processing chamber 114 can be under atmospheric controls and the continuous roll-to-roll deposition coating apparatus 100 can comprise an entrance vacuum lock system 200 at an entrance side 202 of the vacuum process chamber 114 and an exit vacuum lock system 204 at an exit side 206 of the vacuum process chamber 114. In other embodiments, the supply chamber 102, the vacuum process chamber 114, and the collection chamber 110 are all under atmospheric controls.

Atmospheric controls can include maintaining the vacuum process chamber 114 at a specified operating pressure. Atmospheric controls can also include maintaining the supply chamber 102 and the collection chamber 110 each at a specified operating pressure. The specified operating pressure does not need to be the same for each chamber. An example operating pressure is maximally 1×10⁻² mbar. Atmospheric controls can also optionally include maintaining an atmosphere in at least the vacuum process chamber 114 that includes no reactive gases or a specified gas or gas concentration.

In one example, both the uncoiler 104 and the recoiler 112 are under atmospheric controls. For example, the uncoiler 104 and the recoiler 112 can be under vacuum and have the requisite equipment, e.g., vacuum pumps, connected to these two chambers (not shown).

Between the supply chamber 102 and the vacuum process chamber 114 there is a vacuum lock system 200 with strip guides similar to strip guides 188 located in the vacuum process chamber 114. In one example, the strip substrate 106 can pass through a narrow section so that one avoids gas diffusion from the supply chamber 102 into the vacuum process chamber 114. In another example, the supply chamber 102 can be at a lower pressure than the vacuum process chamber 114, or at least a lower pressure than the etching zone 116, such that the gas from the etching zone 116, e.g., Ar gas, diffuses into the supply chamber 102 and “residual gas” from the supply chamber 102 does not flow into the vacuum process chamber 114.

In another example, between the etching zone 116 and the deposition zone 118 there is an intermediate vacuum lock system 210 with strip guides similar to strip guides 188 located in the vacuum process chamber 114. A pump capacity in the intermediate vacuum lock system 210 is larger than the pump capacity in the deposition zone 118 and larger than the pump capacity in the etching zone 116 to develop and maintain a lower pressure in the intermediate vacuum lock system 210 relative to each of the deposition zone 118 and the etching zone 116 so that reactive gas from the deposition zone 118 is not diffused into the etching zone 116, i.e. the intermediate vacuum lock system 210 functions as a gas lock.

The gas lock can be done in two ways—either with a lower pressure in the vacuum lock system 210, e.g., a chamber in intermediate vacuum lock system 210 is removing the gas diffusing in to it from both the etching zone 116 and the deposition zone 118, or with a higher gas pressure in the intermediate vacuum lock system 210, e.g., a chamber in intermediate vacuum lock system 210 is supplying gas that diffuses into the etching zone 116 and the deposition zone 118, which is acceptable as such diffusion will also block any reactive gas diffusing from the deposition zone 118 to the etching zone 116.

In a further example, between the vacuum process chamber 114 and the collection chamber 110 there is a vacuum lock system 204 similar to the type described with respect to vacuum lock system 200 between the supply chamber 102 and the vacuum process chamber 114.

An example of the pressure relationship in the various chambers, zones, and/or vacuum locks of an exemplary apparatus could be described as follows:
Pressure (supply chamber)<Pressure (etching zone)>Pressure (Intermediate vacuum lock)<Pressure (deposition zone)>Pressure (collection chamber) Eq. 1
or if we are introducing Argon gas in the intermediate chamber:
Pressure (uncoiler)<Pressure (etcher)<Pressure (Intermediate, Argon)>Pressure (deposition)>Pressure (Recoiler) Eq. 2

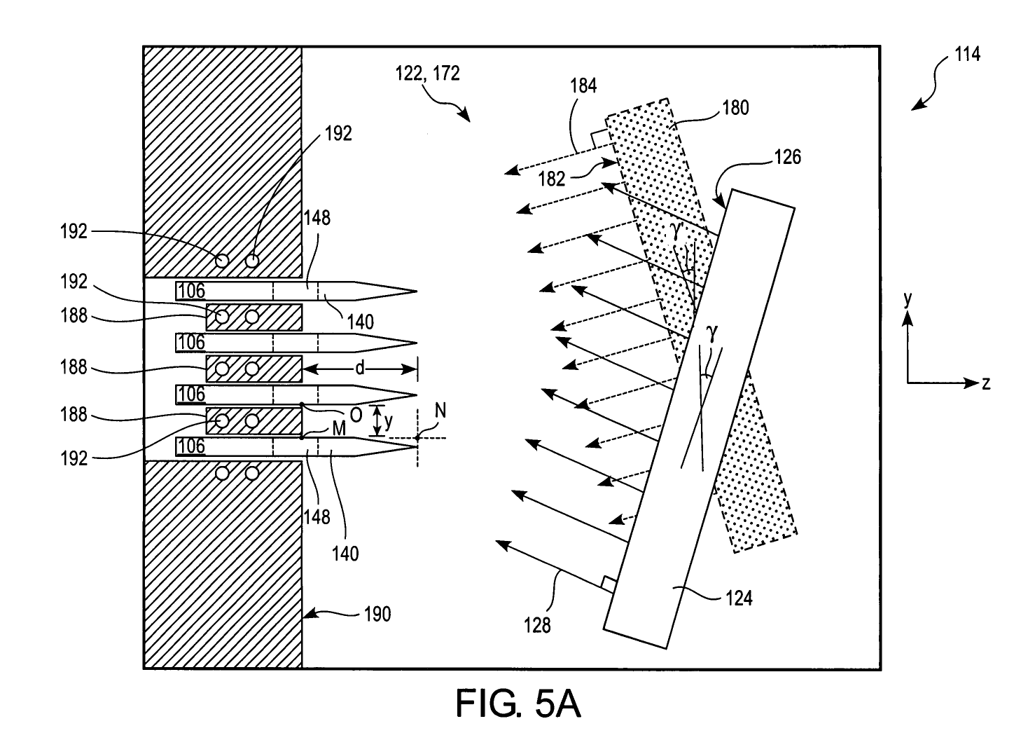

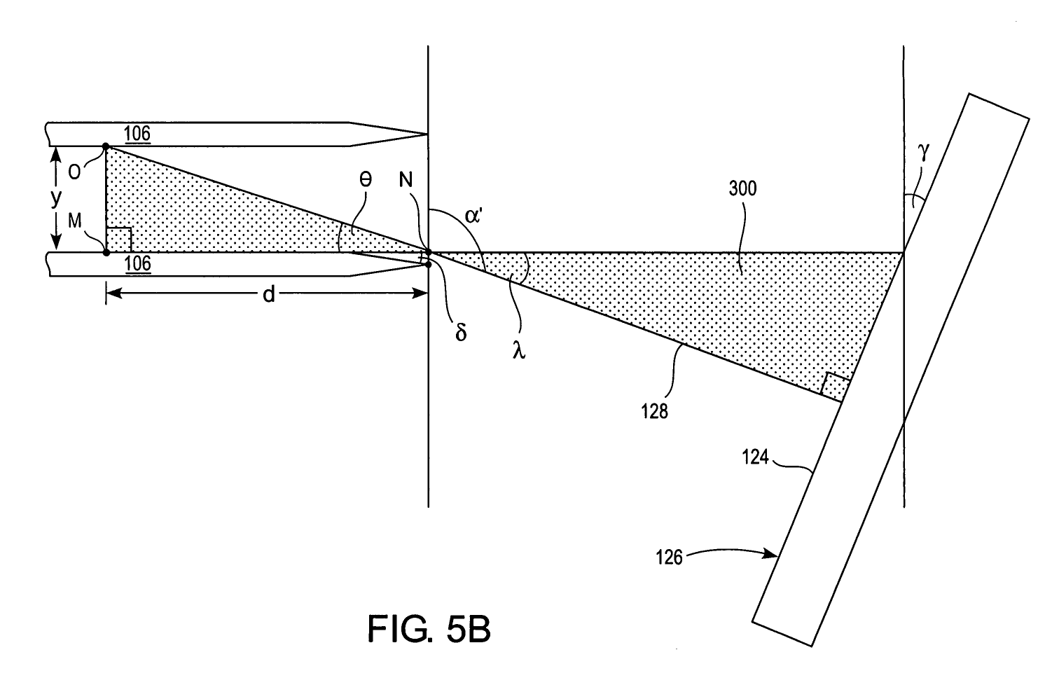

Now an additional exemplary relationship between the projection distance (d) of a strip substrate, the separation distance in the y-axis direction between sequential strip substrates (y) and the angle from the vertical of each of the targets (γ and γ′, respectively) will be shown by reference to FIGS. 5a and 5b.

In FIG. 5a, some of the features of FIG. 2 are represented and similarly labeled with reference characters. In addition, features associated with the lower two strip substrates 106 are illustrated. These include the location on the surface of the lowermost strip substrate where the strip substrate begins to project past the interior surface 190 of the vacuum process chamber 114, indicated by reference character M; the location on a projection of the surface of the lowermost strip substrate that represents the furthest projecting extent of the strip substrate 160, regardless of the shape of the strip substrate (see FIG. 3), indicated by reference character N; and the location on the surface of the next sequential strip substrate where the strip substrate begins to project past the an interior surface 190 of the vacuum process chamber 114, indicated by reference character O. As illustrated, line segment M̅N̅ is representative of the surface of the lower strip substrate that is facing the next sequential strip substrate, whose surface contains point O and the distance of line segment M̅N̅ is d and the separation from line segment M̅N̅ to point O is the distance of line segment M̅O̅ and is illustrated as y.

Referring now to FIG. 5b, where the above geometric positions and features are represented in a highly schematic illustration, the relationship between the angle θ of the triangle formed by MNO and the angle γ, as previously described elsewhere in this specification, can be determined. As illustrated in FIG. 5b, a right triangle MNO can be formed between the two strip substrates 106 having one right angle at M and an angle θ at N. The angle θ is related to the distances of line segments M̅N̅ and M̅O̅ by the following:
θ=tan⁻¹(y/d) Eq. 3

A triangle 300 can be formed as illustrated in FIG. 5b, with a base coincident with the surface 126 of the target 124 and one side formed of the normal 128 that contains the line segment NO from triangle MNO and/or is parallel to the hypotenuse N̅O̅ of triangle MNO. The triangle 300 has one 90-degree angle and an angle λ that is equal to angle θ.

With this information, two additional angles can be determined. First, angle γ can be determined to be equal to angle θ. Therefore, the angle γ for orienting the targets 124 and 180 can be expressed as a function of the spatial position and relationship of the strip substrates 106 as follows:
γ=tan⁻¹(y/d)=θ Eq. 4
A similar relationship can be developed for angle γ ′.

Second, angles α and β can also be expressed as a function of the spatial position and relationship of the strip substrates 106 as follows:
α′=90°+tan⁻¹(y/d) Eq. 5

α′ is approximately equal to α, varying only by any angled surface on the projecting end of the strip substrate 106 (see, e.g., FIG. 3). In a first approximation, this angled surface varies from the planar first surface M̅N̅ by angle δ. Therefore, the angle α can be expressed, in a first approximation, as:
α=α′+δ Eq. 6
A similar relationship can be developed for angle β.

It will be understood that although described and illustrated by reference to the two lower strip substrates of a multiple strip substrate arrangement, the same principles and relationships can be provided for any of the strip substrates of the exemplary continuous roll-to-roll deposition apparatus 100.

The continuous roll-to-roll deposition coating apparatus 100 can deposit coatings on strip substrates in a continuous operation. An exemplary method to continuous coat an edge of a strip substrate comprises supplying at least one strip substrate from a supply chamber to a vacuum process chamber, the strip substrate including a body, a first main side opposing a second main side and a first lateral side opposing a second lateral side, the surfaces of the first and second lateral sides more narrow that the surfaces of the first and second main sides, moving the at least one strip substrate through the vacuum process chamber, the vacuum process chamber including at least one ion assisted etcher in an etching zone and at least one deposition apparatus including at least one target in a deposition zone, the etching zone upstream of the deposition zone, cleaning a first edge region of the at least one strip substrate in the etching zone, the first edge region including at least a first angled surface tapered from a first proximal position toward a first distal position, the first proximal position closer to a center region of the strip substrate than the first distal position, the first angled surface having a first surface normal, depositing a coating on the first angled surface of the first edge region in the deposition zone, and collecting the coated strip substrate in a collection chamber. The at least one strip substrate, in traveling from the supply chamber through the vacuum process chamber to the collection chamber, projects the first edge region toward the at least one ion assisted etcher in the etching zone and projects the first edge region toward the at least one target of the deposition apparatus in the deposition zone. The target of the at least one deposition apparatus includes a target surface having a target normal and is angled with respect to the first angled surface so that the target normal intersects the first surface normal at an angle α. The angle α can be as described herein with respect to embodiments of the apparatus 100. Examples for the angle α include α greater than or equal to 90 degrees, α=from 90 to 135 degrees and α is about 90°+tan⁻¹(y/d), where y is the separation distance in the y-axis direction between sequential strip substrates and d is the projection distance of the strip substrate.

In some embodiments, two surfaces of the strip substrate can be coated. For example, the first edge region of the strip substrate can include a second angled surface on an opposite main side of the strip substrate from the first angled surface. The second angled surface is tapered from a second proximal position toward a second distal position, where the second proximal position is closer to the center region of the strip substrate than the second distal position. The second angled surface has a second surface normal. In this example, the method comprises cleaning the second edge region of the at least one strip substrate in the etching zone, and depositing a coating on the second angled surface of the first edge region in the deposition zone.

The exemplary method can employ one or more etching zones including one or more ion assisted etchers and can employ one or more deposition zones including one or more deposition apparatus. For example, a second (or subsequent or third or fourth or so forth) deposition apparatus including a second (or subsequent or third or fourth or so forth) target can be in the deposition zone. The second (or subsequent or third or fourth or so forth) arc-evaporator or sputterer is downstream in a process flow direction from the at least one arc-evaporator or sputterer. The second target includes a target surface having a target normal and is angled with respect to the second angled surface so that the target normal intersects the second surface normal at an angle β. The angle β can be as described herein with respect to embodiments of the apparatus 100. Examples for the angle β include β greater than or equal to 90 degrees, β=from 90 to 135 degrees, and β is about 90°+tan⁻¹(y/d), where y is the separation distance in the y-axis direction between sequential strip substrates and d is the projection distance of the strip substrate. In some examples, α is equal to β, and in other examples α is not equal to β. In this example, depositing the coating on the second angled surface of the first edge region in the deposition zone includes depositing the coating with the second arc-evaporator or sputterer.

In all of the exemplary methods, additional manipulation of the targets can be performed through the degrees of freedom given the target holder, e.g., one-degree of freedom, two-degrees of freedom, or three-degrees of freedom.

The exemplary method can optionally comprise controlling a supply speed and a collection speed of the strip substrate through the vacuum process chamber to attain a desired tension of the strip substrate in the deposition zone.

The position of the strip substrate within the vacuum process chamber can be controlled to influence the desired placement and quality of the coating. For example, the projecting first edge region of each of the plurality of strip substrates can project the same distance. Here, the angling of the target surface relative to the surface to be coated contributes to neighboring strip substrates not shadowing the surface to be coated. In another example, the projecting first edge region of each of the plurality of strip substrates projects a different distance. Here, both the differing projecting distance and the angling of the target surface relative to the surface to be coated contribute to neighboring strip substrates not shadowing the surface to be coated. Other examples of the positioning of the strip substrates include the first distal position of each of the plurality of strip substrates being staggered and the first distal position of a lower most strip substrate is at a first distance, the first distal position of an uppermost strip substrate is at a second distance, and the second distance is greater than the first distance. A still further example includes the first distal position of each of the plurality of strip substrates between the lowermost strip substrate and the uppermost strip substrate being at a graduated distance between the first distance and the second distance.

The method can optionally control the atmosphere of one or more regions of the apparatus. For example, the vacuum process chamber can have a controlled atmosphere and an entrance vacuum lock system can be at an entrance side of the vacuum process chamber and an exit vacuum lock system can be at an exit side of the vacuum process chamber. The etching zone and deposition zone are also separated by a vacuum lock system. In this example, the method comprises moving the at least one strip substrate through the entrance vacuum lock system and the exit vacuum lock system. In another example, the supply chamber and the collection chamber can, in addition to the vacuum process chamber, also be at a controlled atmosphere. An example of a controlled atmosphere includes maintaining the vacuum process chamber at an operating pressure of maximally 1×0-2 mbar, controlling the supply chamber and the collection chamber each at an operating pressure of maximally 1×10⁻² mbar, controlling the vacuum process chamber at an atmosphere that includes no reactive gases, or combinations of these methods. Additional atmospheric controls can be included for the pressure relationship in the various chambers, zones, and/or vacuum locks of an exemplary apparatus, as described by, for example, Eqs. 1 and 2.

The deposited coating can be as described variously herein, including materials, thickness, hardness and tensile strength. For example, a thickness of the coating is in total maximally 25 μm and a tensile strength of the steel strip substrate is at least 1200 MPa.

In addition and for example, the target source of the first arc-evaporator or sputterer can be a different material than the target source of the second arc-evaporator or sputterer and the coating can have a mixed composition or a layered composition of the materials or the different materials can be deposited on different surfaces of the strip substrate. In addition and for example, the target source of the first arc-evaporator or sputterer can be a same material as the target source of the second arc-evaporator or sputterer and the coating can be deposited on the same or different surfaces of the strip substrate.

The strip substrate material has a composition suitable for hardening, which means, for example:
Hardenable carbon steel of 0.1-1.5% C, 0.001-4% Cr, 0.01-1.5% Mn, 0.01-1.5% Si, up to 1% Ni, 0.001-0.5% N, rest essentially Fe; or
Hardenable chromium steels of 0.1-1.5% C, 10-16% Cr, 0.001-1% Ni, 0.01-1.5% Mn, 0.01-1.5% Si, up to 3% Mo, 0.001-0.5% N, rest essentially Fe; or
Precipitation hardenable steels of: 0.001-0.3% C, 10-16% Cr, 4-12% Ni, 0.1-1.5% Ti, 0.01-1.0% Al, 0.01-6% Mo, 0.001-4% Cu, 0.001-0.3% N, 0.01-1.5% Mn, 0.01-1.5% Si, rest essentially Fe.

### EXAMPLE 1

The chemical compositions of the substrate materials in the example are according to the internal Sandvik designation 20C2 and 13C26, with essentially the following nominal composition:

Sandvik 20C2: 1.0% C, 1.4% Cr, 0.3% Si and 0.3% Mn (by weight); and

Sandvik 13C26: 0.7% C, 13% Cr, 0.4% Si and 0.7% Mn (by weight).

Firstly, the substrate materials are produced by ordinary metallurgical steelmaking to a chemical composition as described above. After this, they are hot-rolled down to an intermediate size, and thereafter cold-rolled in several steps with a number of recrystallization steps between said rolling steps, until a final thickness of 0.2 mm and a width of maximally 400 mm. Thereafter, the strip steels are hardened and tempered to the desired mechanical strength level, which is preferably at least 1200 MPa. The full width strip is thereafter slitted into the final widths of the product. The edges along the slitted strip are then edge-treated, for example shaved, ground and polished, to the conditions and geometry considered suitable for the intended application which includes round edge, sharp-cornered edge, square edge, deburred edge and beveled edge. The surface and the edges of the substrate material are then cleaned to remove oil residuals from the previous operations prior to the coating process.

Thereafter, the coating process takes place in a continuous process line, starting with decoiling equipment, which is placed in a separate vacuum or low pressure decoiling chamber. The first step in the roll-to-roll process line can be a vacuum chamber and/or an entrance vacuum lock followed by an etch chamber, in which ion assisted etching takes place in order to remove the thin oxide layer on the edges of the substrate material to be coated. The strip then enters into the deposition chamber(s) in which the deposition of the coating on the edges takes place. In this example, TiN is selected as the material to be deposited. A metal nitride layer of normally 0.1 up to 25 μm is deposited on the edge; the preferred thickness depends on the application. In the examples described here, a thickness of 2 μm is deposited by using one arc-evaporation chamber. After the arc-evaporation, the coated strip material passes through the exit vacuum chamber or exit vacuum lock before it is being coiled on to a coiler.

The end product as described here, i.e., a coated 20C2 and 13C26-strip material, respectively, in a strip thickness of 0.2 mm and with a thin coating of TiN of 2 μm, has a very good adhesion of the coated layer and is thus suitable to use especially for the manufacturing of doctor blades for flexogravure or rotogravure printing and for industrial knives.

### EXAMPLE 2

The chemical composition of the substrate material in this example is according to the internal Sandvik designation 20C with essentially the following nominal composition:

Sandvik 20C, 1.0% C, 0.2% Cr, 0.3% Si and 0.4% Mn (by weight).

Firstly, the substrate material is produced by ordinary metallurgical steelmaking to a chemical composition as described above. The material is then hot-rolled down to an intermediate size, and thereafter cold-rolled in several steps with a number of recrystallization steps between said rolling steps, until a final thickness of 0.45 mm and a width of maximum 400 mm are attained. Thereafter, the steel strip is hardened and tempered to the desired mechanical strength level, which is preferably above 1200 MPa. The full width strip is thereafter slitted into the final widths of the product, which in this example is 100 mm for a coater blade application. The edges along the slitted strip are then edge-treated, for example shaved, ground and polished, to the conditions and geometry considered suitable for the intended application which includes round edge, sharp-cornered edge, square edge, deburred edge and beveled edge. The surface and the edges of the substrate material are then cleaned to remove oil residuals from the previous operations prior to the coating process.

The end product will be a coated strip, the coating material and thickness being the same as in Example 1. Now, the coated strip material can be slitted in the middle along section 206 to obtain two coated strips, each with the dimension and edge geometry suitable for a finished application. In principle, only cutting into required final length remains.

The end product as described in this example, i.e., a slitted, edge treated and coated strip substrate material, in a strip thickness of 0.45 mm and a final slitted width of 100 mm, has a thin edge covering titanium nitride layer of 2 μm with a very good adhesion of the coated layer. This product can be cut into required length, depending on the final application without any further processing, e.g., normally in between 3 to 10 m, and then used as a coater blade in a paper mill.

Exemplary forms of the coated steel products described herein can be used in applications where a hard, dense, and/or low friction wear resistant coating may be suitable, such as: scissors and pruning shears, kitchen and bakery tools, handtools for plastering, trowels, medical instruments and surgical knives, razor blades, cutters, flapper valves, die cutting tools, saws and various knives in general, such as utility knives, e.g., slicers, carving knives, bread knives, butcher's knives, mixer blades, hunting and fishing knives, pocket knives and industrial knives for cutting synthetic fiber, paper, plastic film, fabrics and carpets, coater and doctor blades or other applications using a metal strip substrate with a coated edge.

Thus, a strip material according to the exemplary embodiments is also suitable to use in shaving equipment such as razor blades and cutters, and medical instruments such as thin surgical knives. The thickness of the substrate material is rather thin in these types of applications, normally between 0.015 to 0.75 mm and usually 0.015 to 0.6 mm and preferably 0.03 to 0.45 mm. The thickness of the coating can accordingly preferably be as thin as possible, normally in total between 0.1 to 5 μm and usually 0.1 to 3 μm and preferably 0.1 to 2 μm or even more preferably 0.1 to 1 μm. In this case, it is thus preferred to have a small ratio between the thickness of the coating and the thickness of the strip material. The ratio is normally between 0.01% to 7% and preferably between 0.01 to 5%.

One further use of these exemplary embodiments is that the coating may be applied before the hardening and tempering treatment of the substrate material. The coating should, in this case, be able to withstand a hardening temperature of minimum 400° C. and preferably more than 800° C., and more preferably above 950° C., for holding times at hardening temperatures normally used in a hardening of said substrate material so as to obtain a tensile strength, i.e., a minimum tensile strength of 1200 MPa.

For further illustration, typical dimensions in the case of a strip material for razor blades would be a substrate material with a thickness below 0.15 mm, normally less than 0.10 mm, and a strip width of about 400 mm and a coating thickness of below 5 μm, usually 2 μm, normally less than around 1 μm, or even thinner.

A strip material according to exemplary embodiments is suitable to use also in various utility and industrial knife applications and also saw applications. The thickness of the substrate material is relatively thick in this type of application, normally between 0.1 to 5 mm and usually between 0.2 to 3 mm. The thickness of the coating is however kept as thin as possible, normally in total between 0.1 to 10 μm and usually 0.1 to 5 μm and preferably 0.1 to 3 μm or even more preferably 0.1 to 2 μm. In this case, it is thus preferred to have a small ratio between the thickness of the coating and the thickness of the strip material. The ratio is normally between 0.002% to 7% and preferably between 0.01 to 5%.

Another further use of these exemplary embodiments is that the coating may be applied before the hardening and tempering treatment of the substrate material. The hard and dense coating should in this case be able to withstand a hardening temperature of minimum 400° C. and preferably more than 800° C., and more preferably above 950° C., for holding times at hardening temperature normally used in a hardening of said substrate material so as to obtain a tensile strength, i.e., a minimum of 1200 MPa.

Examples 1 and 2 above both show exemplary embodiments that in an analogous way apply for razor blades and/or thin surgical knives and/or utility and industrial knives and/or saw applications. Thus, these examples illustrate coating methods and substrate materials suitable for these applications. The only difference is the sequence order for hardening and tempering, which can be altered with the coating, as also described above.

Although the present invention has been described in connection with preferred embodiments thereof, it will be appreciated by those skilled in the art that additions, deletions, modifications, and substitutions not specifically described may be made without department from the spirit and scope of the invention as defined in the appended claims.

What is claimed is:

1. A continuous roll-to-roll deposition coating apparatus, comprising:
a vacuum process chamber including an etching zone upstream of a deposition zone;
at least one ion assisted etcher in the etching zone; and
at least one deposition apparatus in the deposition zone, wherein the at least one deposition apparatus includes at least one target,
wherein the strip substrate, in traveling through the vacuum process chamber, projects a first edge region toward the at least one ion assisted etcher in the etching zone and projects the first edge region toward the target of the at least one deposition apparatus in the deposition zone,
wherein the first edge region of the strip substrate includes at least a first angled surface tapered from a first proximal position toward a first distal position, the first proximal position closer to a center region of the strip substrate than the first distal position, the first angled surface having a first surface normal, and
wherein the target of the at least one deposition apparatus includes a target surface having a target normal and is angled with respect to the first angled surface so that the target normal intersects the first surface normal at an angle α, where α is greater than or equal to 90 degrees.

2. The continuous roll-to roll deposition coating apparatus of claim 1, wherein α=from 90 to 135 degrees.

3. The continuous roll-to roll deposition coating apparatus of claim 1, wherein α is about 90°+tan⁻¹(y/d), where y is the separation distance in the y-axis direction between sequential strip substrates and d is the projection distance of the strip substrate.

4. The continuous roll-to-roll deposition coating apparatus of claim 1, wherein the first distal position of the first angled surface is coextensive with an edge of the strip substrate.

5. The continuous roll-to-roll deposition coating apparatus of claim 1, comprising a second deposition apparatus in the deposition zone,
wherein the second deposition apparatus includes a second target,
wherein the second deposition apparatus is downstream in a process flow direction from the at least one deposition apparatus,
wherein the first edge region of the strip substrate includes a second surface on an opposite main side of the strip substrate from the first angled surface, and
wherein the second target of the second deposition apparatus includes a target surface having a target normal and is angled with respect to the second surface of the strip substrate so that the target normal intersects the second surface normal at an angle β, where β is greater than or equal to 90 degrees.

6. The continuous roll-to-roll deposition coating apparatus of claim 1, wherein the first edge region of the strip substrate includes a second angled surface on an opposite main side of the strip substrate from the first angled surface, wherein the second angled surface is tapered from a second proximal position toward a second distal position, and wherein the second proximal position is closer to the center region of the strip substrate than the second distal position, the second angled surface having a second surface normal.

7. The continuous roll-to-roll deposition coating apparatus of claim 6, wherein the second distal position of the second angled surface is coextensive with an edge of the strip substrate.

8. The continuous roll-to-roll deposition coating apparatus of claim 6, wherein the first distal position of the first angled surface and the second distal position of the second angled surface are coterminous and form a knife-edge.

9. The continuous roll-to-roll deposition coating apparatus of claim 6, comprising a second deposition apparatus in the deposition zone,
wherein the second deposition apparatus includes a second target,
wherein the second deposition apparatus is downstream in a process flow direction from the at least one deposition apparatus, and
wherein the second target of the second deposition apparatus includes a target surface having a target normal and is angled with respect to the second angled surface so that the target normal intersects the second surface normal at an angle β, where β is greater than or equal to 90 degrees.

10. The continuous roll-to roll deposition coating apparatus of claim 9, wherein β=from 90 to 135 degrees.

11. The continuous roll-to roll deposition coating apparatus of claim 9, wherein β=is about 90°+tan⁻¹(y/d), where y is the separation distance in the y-axis direction between sequential strip substrates and d is the projection distance of the strip substrate.

12. The continuous roll-to roll deposition coating apparatus of claim 9, wherein α≠β.

13. The continuous roll-to roll deposition coating apparatus of claim 9, wherein the target of the first deposition apparatus is a different material than the target of the second deposition apparatus.

14. The continuous roll-to roll deposition coating apparatus of claim 9, wherein the target of the first deposition apparatus is a same material as the target of the second deposition apparatus.

15. The continuous roll-to roll deposition coating apparatus of claim 9, comprising:
a supply chamber including an uncoiler for each of a plurality of strip substrate each arranged in a coil; and
a collection chamber including a recoiler for each of the plurality of strip substrate;
wherein the vacuum process chamber is between the supply chamber and the collection chamber.

16. The continuous roll-to roll deposition coating apparatus of claim 15, comprising a controller operatively connected to the uncoiler for each of the plurality of coils and the recoiler for each of the plurality of strip substrates, wherein the strip substrate travels from the supply chamber through the vacuum process chamber to the collection chamber and the controller controls the speed of supply and collection of the strip substrate through the vacuum process chamber to attain a desired tension of the strip substrate in the deposition zone.

17. The continuous roll-to roll deposition coating apparatus of claim 1, wherein the plurality of strip substrates are spaced apart horizontally with an optional spacer between successive strip substrates.

18. The continuous roll-to roll deposition coating apparatus of claim 1, wherein the projecting first edge region of each of the plurality of strip substrates project the same distance.

19. The continuous roll-to roll deposition coating apparatus of claim 1, wherein the projecting first edge region of each of the plurality of strip substrates project a different distance.

20. The continuous roll-to roll deposition coating apparatus of claim 19, wherein the first distal position of each of the plurality of strip substrates between the lowermost strip substrate and the uppermost strip substrate is at a graduated distance between the first distance and the second distance.

21. The continuous roll-to-roll deposition coating apparatus of claim 1, wherein the continuous roll-to-roll deposition coating apparatus is under atmospheric controls.

22. The continuous roll-to-roll deposition coating apparatus of claim 1, wherein the vacuum process chamber has an atmosphere that includes no reactive gases.

23. The continuous roll-to-roll deposition coating apparatus of claim 1, wherein the strip substrate is a substrate of a coater blade, a doctor blade, a piece of shaving equipment, a medical instrument, an utility knife or an industrial knife.

24. A method to continuous coat an edge of a strip substrate, comprising:
supplying at least one strip substrate to a vacuum process chamber, the strip substrate including a body, a first main side opposing a second main side and a first lateral side opposing a second lateral side, the first and second lateral sides more narrow that the first and second main sides;
moving the at least one strip substrate through the vacuum process chamber, the vacuum process chamber including at least one ion assisted etcher in an etching zone and at least one deposition apparatus in a deposition zone, the etching zone upstream of the deposition zone;
cleaning a first edge region of the at least one strip substrate in the etching zone, the first edge region including at least a first angled surface tapered from a first proximal position toward a first distal position, the first proximal position closer to a center region of the strip substrate than the first distal position, the first angled surface having a first surface normal;
depositing a coating on the first angled surface of the first edge region in the deposition zone; and
collecting the coated strip substrate,
wherein the at least one deposition apparatus includes at least one target,
wherein the at least one strip substrate, in traveling through the vacuum process chamber, projects the first edge region toward the at least one ion assisted etcher in the etching zone and projects the first edge region toward the at least one target of the at least one deposition apparatus in the deposition zone, and
wherein the target of the at least one deposition apparatus includes a target surface having a target normal and is angled with respect to the first angled surface so that the target normal intersects the first surface normal at an angle α, where α is greater than or equal to 90 degrees.

25. The method of claim 24, wherein α=from 90 to 135 degrees.

26. The method of claim 24, wherein α is about 90°+tan⁻¹(y/d), where y is the separation distance in the y-axis direction between sequential strip substrates and d is the projection distance of the strip substrate.

27. The method of claim 24, wherein the first edge region of the strip substrate includes a second surface on an opposite main side of the strip substrate from the first angled surface, and
wherein the method comprises:
cleaning the second edge region of the at least one strip substrate in the etching zone, and
depositing a coating on the second angled surface of the first edge region in the deposition zone.

28. The method of claim 27, wherein a second deposition apparatus is located in the deposition zone,
wherein the second deposition apparatus includes at least one target,
wherein the second deposition apparatus is downstream in a process flow direction from the at least one deposition apparatus,
wherein the at least one target of the second deposition apparatus includes a target surface having a target normal and is angled with respect to the second surface so that the target normal intersects the second surface normal at an angle β, where β is greater than or equal to 90 degrees, and
wherein depositing the coating on the second surface of the first edge region in the deposition zone includes depositing the coating with the second deposition apparatus.

29. The method of claim 24, wherein the first edge region of the strip substrate includes a second angled surface on an opposite main side of the strip substrate from the first angled surface, wherein the second angled surface is tapered from a second proximal position toward a second distal position, and wherein the second proximal position is closer to the center region of the strip substrate than the second distal position, the second angled surface having a second surface normal, and
wherein the method comprises:
cleaning the second edge region of the at least one strip substrate in the etching zone, and
depositing a coating on the second angled surface of the first edge region in the deposition zone.

30. The method of claim 29, wherein a second deposition apparatus is located in the deposition zone,
wherein the second deposition apparatus includes at least one target,
wherein the second deposition apparatus is downstream in a process flow direction from the at least one deposition apparatus,
wherein the at least one target of the second deposition apparatus includes a target surface having a target normal and is angled with respect to the second angled surface so that the target normal intersects the second surface normal at an angle β, where β is greater than or equal to 90 degrees, and
wherein depositing the coating on the second angled surface of the first edge region in the deposition zone includes depositing the coating with the second deposition apparatus.

31. The method of claim 30, wherein β=90 to 135 degrees.

32. The method of claim 30, wherein β is about 90°+tan⁻¹(y/d), where y is the separation distance in the y-axis direction between sequential strip substrates and d is the projection distance of the strip substrate.

33. The method of claim 30, wherein α≠β.

34. The method of claim 30, wherein the target of the first deposition apparatus is a different material than the target of the second deposition apparatus.

35. The method of claim 30, wherein the target of the first deposition apparatus is a same material as the target of the second.

36. The method of claim 24, comprising:
controlling a supplying speed and a collection speed of the strip substrate through the vacuum process chamber to attain a desired tension of the strip substrate in the deposition zone.

37. The method of claim 24, wherein the projecting first edge region of each of the plurality of strip substrates project the same distance.

38. The method of claim 24, wherein the projecting first edge region of each of the plurality of strip substrates project a different distance.

39. The method of claim 38, wherein the first distal position of each of the plurality of strip substrates between the lowermost strip substrate and the uppermost strip substrate is at a graduated distance between the first distance and the second distance.

40. The method of claim 24, comprising controlling the atmosphere in at least the vacuum process chamber.

41. The method of claim 40, wherein the at least one strip substrate is supplied from a supply chamber and wherein the coated strip substrate is collected in a collection chamber and the method comprises controlling the atmosphere in at least one of the supply chamber and the collection chamber.

42. The method of claim 24, wherein the vacuum process chamber has an atmosphere that includes no reactive gases.

43. The method of claim 24, wherein a thickness of the coating is in total maximally 25 μm and a tensile strength of the steel strip substrate is at least 1200 MPa.

44. The method of claim 24, wherein the coating is a metallic coating comprising Cr or Ni.

45. The method of claim 42, wherein the thickness of the strip substrate is between 0.015 mm and 5.0 mm.

46. The method of claim 42, wherein the strip substrate is made of hardenable carbon steel, hardenable stainless chromium steels, or precipitation hardenable strip steel.

47. The product of claim 24, wherein the coating includes a transition metal nitride, a transition metal carbide, a transition metal carbonitride, a diamond-like carbon or mixtures thereof.

48. The method of claim 24, wherein the coating is a multilayer including a transition metal nitride, a transition metal carbide, a transition metal carbonitride, a diamond-like carbon or mixtures thereof.

49. The method of claim 24, wherein the coating includes a pure metal.

50. The method of claim 24, wherein the coating includes a MAX phase material.

51. The method of claim 24, wherein the coating is a multilayer including up to 20 sublayers.

52. The method of claim 24, wherein the coating comprises at least one layer of nickel having a thickness up to 2 μm, the at least one layer not being adjacent the strip substrate.

53. The method of claim 24, comprising incorporating the coated strip substrate into a coater blade, a doctor blade, a piece of shaving equipment, a medical instrument, an utility knife or an industrial knife.

54. A continuous roll-to-roll deposition coating apparatus, comprising:
a vacuum process chamber including an etching zone upstream of a deposition zone;
at least one ion assisted etcher in the etching zone; and
at least one deposition apparatus in the deposition zone, wherein the at least one deposition apparatus includes at least one target,
wherein the strip substrate, in traveling through the vacuum process chamber, projects a first edge region toward the at least one ion assisted etcher in the etching zone and projects the first edge region toward the target of the at least one deposition apparatus in the deposition zone,
wherein the first edge region of the strip substrate is squared off and has a first proximal position and a first distal position, the first proximal position closer to a center region of the strip substrate than the first distal position, the first edge region having a first surface normal, and
wherein the target of the at least one deposition apparatus includes a target surface having a target normal and is angled with respect to the first edge region so that the target normal intersects the first surface normal at an angle α, where α is greater than or equal to 90 degrees.
